(19) United States
(12) Patent Application Publication
(10) Pub. No.: US 2021/0164813 A1
(43) Pub. Date: Jun. 3, 2021

(54) DEVICE FOR MONITORING AN OBJECT

(71) Applicant: Robert Bosch GmbH, Stuttgart (DE)

(72) Inventors: David Bendes, Budapest (HU); Richard Bartalos, Zanka (HU)

(21) Appl. No.: 16/770,583

(22) PCT Filed: Nov. 8, 2018
(86) PCT No.: PCT/EP2018/080575

§ 371 Date: Jun. 5, 2020

(30) Foreign Application Priority Data
Jan. 12, 2018 (DE) 10 2018 200 510.9

(51) Int. Cl. G01D 11/30; G01K 1/14; G01L 19/14; G01P 1/02; G01R 1/04

(52) U.S. Cl. CPC G01D 11/30; G01K 1/14; G01R 1/04; G01P 1/02; G01L 19/14

(57) ABSTRACT

A device for monitoring an object. The device includes an electronic unit for detecting and storing at least one surroundings parameter acting on the object. The device includes a support element, which is designed to be adhesive on a top side and on a bottom side, the electronic unit being situated on the top side of the support element and being adhesively connected to the top side of the support element, and the device being adhesively mountable at the object with the aid of the underside of the support element.

### BACKGROUND INFORMATION

The present invention is directed to a device for monitoring an object, the device including an electronic unit for detecting and storing at least one surroundings parameter acting on the object. Such devices typically have the problem, however, that they are made up of a plurality of subcomponents, by which the manufacture of such a device is complex and expensive.

In addition, conventional simple monitoring devices typically manage without electronic components. Such monitoring devices may only indicate that an appropriate threshold value has been exceeded. However, no inferences may be drawn regarding the changes over time of the corresponding surroundings parameters. In addition, these display options are often irreversible.

### SUMMARY

The present invention is directed to a device for monitoring an object, the device including an electronic unit for detecting and storing at least one surroundings parameter acting on the object.

An electronic unit is understood to mean, in this case, that the electronic unit encompasses electronic components, such as a sensor unit and/or a processing unit and/or a memory element and/or a communication unit and/or a switching element.

Detection and storage of the surroundings parameter is understood to mean that the appropriate surroundings parameter is detected continuously or at an appropriate scanning frequency during the monitoring of the object and the detected measured values are appropriately stored, so that a corresponding measured value profile may be read out of the memory element subsequent to the monitoring.

According to one aspect of the present invention, an example device includes a support element, which is designed to be adhesive on a top side and on a bottom side, the electronic unit being situated on the top side of the support element and being adhesively connected to the top side of the support element, and the device being adhesively mountable on the object via the bottom side of the support element.

It is advantageous, in this case, that the device is very simply designed and is formed of only two parts, namely the support element and the electronic unit. As a result, the manufacturing cost of the device may be kept low. The support element has a dual function in this case. On the one hand, the electronic unit is fixed on the support element. On the other hand, the device may be mounted on an object with the aid of the support element, in order to monitor the object. Such an object may be, for example, goods to be transported.

Additionally or alternatively, it is also possible that the device be nailed and/or stapled and/or screwed, for example, onto an appropriate object, in order to fasten the device to the object. Further alternatives to the mounting of the device on an object are, for example, a crimp connection and/or a clamping connection or a rivet connection or a detent connection or a hook-and-loop fastener.

According to one further advantage, the example device according to the present invention may be utilized for monitoring an object, in that the device is situated in an object or at the object or in the surroundings of the object. For this purpose, an appropriately designed electronic unit encompasses, in particular, a sensor unit for detecting at least one surroundings parameter acting upon the object as well as a memory element for storing the at least one detected surroundings parameter. On the basis of the detected and stored surroundings parameter, a check may be carried out to determine whether the object was handled properly, for example, during transport. For example, depending on the design of the sensor unit, a check may be carried out to determine whether the object was exposed to impacts or if threshold values for moisture and/or temperature were exceeded.

The low weight of the example device as compared to typical, complex devices also offers the advantage that a lesser attenuation of external effects upon the electronic unit takes place and, therefore, a lesser effect of the detection of the surroundings parameters acting upon an object takes place.

In one example embodiment of the device according to the present invention, it is provided that the support element is a foil, which is, in particular, a double-sided adhesive tape.

It is advantageous in this case that such a foil is very easily and cost-effectively manufactured. Additionally, a support element designed as a foil has a considerably lower weight than an injection molded part, by which, for example, transport costs of the device may be reduced. Moreover, a foil may be designed to be flexible, by which, for example, unevenness of the electronic unit or of the object may be compensated for, which results in a better adhesion between the support element and the electronic unit or the object.

Foil is understood to be an object, which is designed in such a way that its thickness is smaller, by several orders of magnitude, with respect to its width and with respect to its length.

In one example embodiment of the device according to the present invention, it is provided that the device includes a housing, which encompasses a first housing part and a second housing part, the support element being designed as the first housing part, and the second housing part being designed and situated in such a way that the electronic unit is at least partially enclosed by the housing. In particular, the first housing part and/or the second housing part are/is designed as a foil. Such a housing encompassing at least one housing part designed as a foil is typically referred to as blister packaging.

It is advantageous in this case that a housing may protect the electronic unit from undesirable, external effects, such as contamination or moisture. Moreover, a housing part designed as a foil may be manufactured considerably more cost-effectively than, for example, a housing part manufactured with the aid of an injection molding process. As a result, the costs for the device may be correspondingly reduced, costs being understood to be the manufacturing costs as well as the material costs. Despite these low costs, the housing parts designed as a foil offer a possibility for protecting the electronic unit from undesirable, external effects. In this way, an international protection code according to IP54 or higher may be achieved.

In one example embodiment of the device according to the present invention, it is provided that the device is at least partially covered by a coating, in particular the electronic unit being at least partially covered by the coating.

It is advantageous in this case that the coating may also protect the device and the electronic unit from undesirable external effects, such as dust or moisture. In addition, the coating may impart a certain hold to the electronics components of the electronic unit, whereby the device becomes more stable and may have a longer service life.

A varnish or a sealing compound, for example, may be utilized as coating. This coating is situated, in this case, in particular, in the interior of the housing.

In one example embodiment of the device according to the present invention, it is provided that the electronic unit is configured for outputting pieces of information regarding the object, in particular pieces of information regarding the at least one surroundings parameter acting upon the object.

It is advantageous in this case that a user or an external unit may receive and evaluate the pieces of information. Based on the evaluation, an appropriate response by the user or by the external unit may then take place.

In one example embodiment of the device according to the present invention, it is provided that the electronic unit encompasses a display element and is configured for outputting the pieces of information with the aid of the display element, the display element including, in particular, a display and/or, in particular, an illuminant.

It is advantageous that this represents a simple option for outputting the pieces of information. In particular, such visually output pieces of information are understood very well and quickly by a user. The initiative for such an information transmission may take place manually, for example, initiated by the user, or also automatically, for example, at predefined time intervals or permanently.

In one example embodiment of the device according to the present invention, it is provided that the electronic unit encompasses a transducer element and is configured for converting the pieces of information into mechanical oscillations and outputting these with the aid of the transducer element, the transducer element encompassing, in particular, a loudspeaker.

It is advantageous that this represents one further simple possibility for transmitting the appropriate pieces of information, in particular, to a user. The initiative for such an information transmission may take place manually, for example, initiated by the user, or also automatically, for example, at predefined time intervals or permanently.

In one example embodiment of the device according to the present invention, it is provided that the electronic unit encompasses a communication unit for communication with an external unit, in particular a wireless communication unit. It is advantageous that pieces of information may be transmitted from the device to the external unit, such as the present state of the monitoring operation or detected surroundings parameters, and that data may also be transmitted from the external unit to the device, in order, for example, to update the device or also to start or also terminate a monitoring operation.

Alternatively or additionally, the communication unit may also be designed to be hard-wired.

In one example embodiment of the device according to the present invention, it is provided that the electronic unit encompasses an energy supply unit, in particular an energy store and/or in particular an energy harvesting unit, the energy store particularly preferably encompassing a battery and/or particularly preferably a capacitor.

It is advantageous that the device does not need to be connected to an electrical network and, as a result, may be utilized, problem-free, in particular in the monitoring of mobile objects.

In one example embodiment of the device according to the present invention, it is provided that the electronic unit encompasses at least one memory element and at least one sensor unit, the sensor unit including, in particular, an acceleration sensor and/or, in particular, a rotation rate sensor and/or, in particular, a sound transducer and/or, in particular, an inclination sensor and/or, in particular, a light sensor and/or, in particular, a magnetic field sensor and/or, in particular, a temperature sensor and/or, in particular, a pressure sensor and/or, in particular, a moisture sensor.

It is advantageous that the appropriate surroundings parameter may be detected and stored. On the basis of the surroundings parameters, it may be inferred whether the object, at which the device is mounted and which is therefore monitored with the aid of the device, has been properly handled or not. In this way, a check may be carried out to determine, for example, whether predefined threshold values, for example, for the acceleration or the temperature, have been exceeded. If this is the case, it may be inferred, for example, that the object was exposed to strong impacts or to an excessively high or excessively low temperature.

According to one example embodiment of the device according to the present invention, it is provided that the electronic unit encompasses at least one switching element.

It is advantageous that, with the aid of the switching element, appropriate control commands may be transmitted by a user to the electronic unit of the device. The switching element may encompass, for example, a pushbutton and/or a toggle switch.

Alternatively or additionally, the switching element may also encompass a contactless switch, for example, a reed switch.

The switching element may be situated, for example, in such a way that it may be actuated through the housing, i.e., for example, also through the support element. For this purpose, the housing and a coating, which is present, if necessary, must therefore be designed to be elastic.

The electronic unit may also encompass a circuit, which is designed in such a way that an interaction of the device with a user is made possible. For this purpose, the circuit may encompass, for example, breakable or electrically contactable elements.

According to one example embodiment of the device according to the present invention, it is provided that the housing is designed to be essentially optically transparent or optically transparent in areas.

It is advantageous that optical radiation may exit the interior of the housing and/or enter the interior of the housing. As a result, for example, a possible user may see into the interior of the housing. As a result, for example, pieces of information, which may be emitted by a display element of the electronic unit, are visually detectable by a user.

Optical transparency is to be understood to mean that optical radiation may penetrate the material. In particular, the optical radiation, which may penetrate the material, has a predefined wavelength range. It is also possible, however, that radiation having an arbitrary wavelength may penetrate the material.

According to one example embodiment of the device according to the present invention, it is provided that the foil is a plastic foil, which includes, in particular, a biomaterial.

It is advantageous that a plastic foil does not electromagnetically shield a possible communication unit of the electronic unit. Moreover, upon utilization of a biomaterial, the device may also be used in areas in which specific preconditions are placed upon the utilized materials. This may be the case, for example, in the food sector, in which the material must be, for example, non-toxic.

### BRIEF DESCRIPTION OF THE DRAWING

FIG. 1 shows a section through an exemplary embodiment of a device according to the present invention.

### DETAILED DESCRIPTION OF EXAMPLE EMBODIMENTS

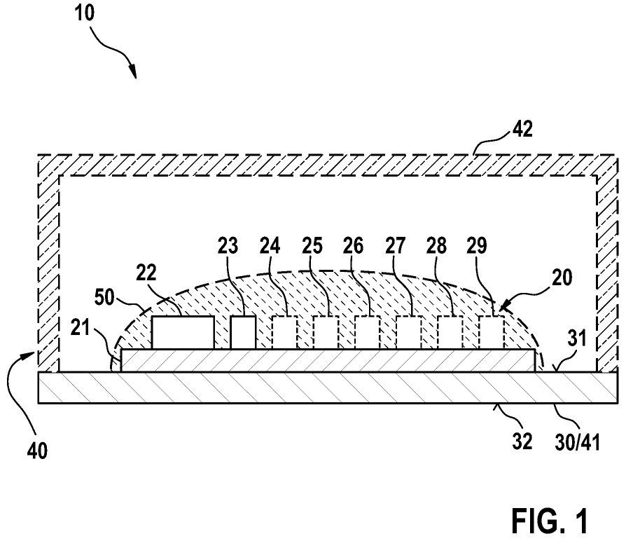

FIG. 1 shows a section through an exemplary embodiment of a device according to the present invention.

A device 10 for monitoring an object (not illustrated) is represented. Device 10 encompasses an electronic unit 20 for detecting and storing at least one surroundings parameter acting upon the object. Electronic unit 20 encompasses a sensor unit 22 and one memory element 23 for detecting and storing at least one surroundings parameter acting upon the object and which are situated on a circuit board 21 of electronic unit 20. Sensor unit 22 may include, in particular, an acceleration sensor and/or, in particular, a rotation rate sensor and/or, in particular, a sound transducer and/or, in particular, an inclination sensor and/or, in particular, a light sensor and/or, in particular, a magnetic field sensor and/or, in particular, a temperature sensor and/or, in particular, a pressure sensor and/or, in particular, a moisture sensor.

In addition, device 10 encompasses a support element 30. Support element 30 is designed as a foil, a top side 31 of support element 30 as well as a bottom side 32 of support element 30 being designed to be adhesive. Such an adhesive design may be achieved, for example, in that support element 30 includes an appropriate double-sided adhesive coating or, however, in that support element 30 includes an adhesive material. In particular, support element 30 is designed as double-sided adhesive tape. Support element 30 may be designed in such a way that it is thick or thin, hard or soft, plastic or elastic, deformable or rigid, heat-resistant or heat-sensitive, porous or solid, one-piece or multiple-piece, flat or shaped, and/or one-layer or multilayer, and/or has different thicknesses and/or recesses. Support element 30 may also be designed, in particular, in such a way that properties of support element 30, for example, the elasticity or optical transparency, differ in certain areas as compared to other areas.

Electronic unit 20 is situated on top side 31 of support element 30 and is adhesively connected to top side 31 of support element 30, in that circuit board 21 is bonded onto top side 31 of support element 30. Moreover, device 10 is adhesively mountable at the object with the aid of bottom side 32 of support element 30.

Optionally, electronic unit 20 may also encompass a display element 24 and/or a transducer element 25 and/or a communication unit 26 and/or an energy supply unit 27 and/or a processing unit 28 and/or a switching element 29, which may be appropriately situated on circuit board 21.

Display element 24 includes, in particular, a display and/or, in particular, an illuminant.

Transducer element 25 is utilized for converting the pieces of information into mechanical oscillations, the transducer element 25 encompassing, in particular, a loudspeaker.

Moreover, communication unit 26 is configured for communicating with an external unit (not depicted). In particular, communication unit 26 encompasses a wireless communication unit, for example, a WLAN unit and/or a Bluetooth unit and/or a LoRa unit and/or a mobile radio communication unit. Alternatively or additionally, communication unit 26 may also be designed to be hard-wired.

Energy supply unit 27 may encompass, in particular, an energy store and/or, in particular, an energy harvesting unit, the energy store including, particularly preferably, a battery and/or, particularly preferably, a capacitor.

Processing unit 28 may be designed, for example, as a microcontroller. In addition, memory unit 23 may also be optionally integrated into processing unit 28.

Switching element 29 is designed, for example, as a pushbutton or toggle switch. Alternatively or additionally, the switching element may also encompass a contactless switch, for example, a reed switch.

Electronic unit 20 is configured, in particular, for outputting pieces of information regarding the object. These pieces of information preferably include pieces of information regarding at least one surroundings parameter acting upon the object. The pieces of information may be emitted, for example, with the aid of display element 24 and/or with the aid of transducer element 25 and/or with the aid of communication unit 26. In addition, electronic unit 20 may be configured for receiving data from an external unit, for example, with the aid of communication unit 26.

Due to the assembly of circuit board 21 with the appropriate electronic components, electronic unit 20 may be designed as a data logger, which may detect and store surroundings parameters. The electronic components may be appropriately connected to one another, the connections being designed to be hard-wired and/or wireless. In order to be able to utilize electronic unit 20 as a data logger, in particular, at least sensor unit 22 and memory element 23 are necessary. As a result, device 10 may be utilized for monitoring an object. This object may be, for example, goods to be transported.

Optionally, device 10 may also encompass a housing 40, which surrounds electronic unit 20. The housing encompasses a first housing part 41 and a second housing part 42. Support element 30 is utilized, in this case, as first housing part 41, and second housing part 42 is designed and situated in such a way that electronic unit 20 is enclosed by housing 40. Alternatively, housing 40 may also only partially surround electronic unit 20.

Second housing part 42 may be designed, in particular, in such a way that it is thick or thin, hard or soft, plastic or elastic, deformable or rigid, heat-resistant or heat-sensitive, porous or solid, one-piece or multiple-piece, flat or shaped, and/or one-layer or multilayer, and/or of different thicknesses. Support element 30 may also be designed, in particular, in such a way that properties of the second housing part, for example, the elasticity or optical transparency, differ in certain areas as compared to other areas.

Housing parts 41, 42 may be manufactured, for example, with the aid of deep drawing of a foil, in particular with the aid of thermoforming. Preferably, this foil may be, for example, a plastic foil, which particularly preferably has a thickness between 0.1 mm and 5 mm. The foil may also encompass, for example, materials, which are conductive, for example, additionally or alternatively, also materials, which are insulating. It is particularly preferred that the plastic foil encompasses a biomaterial. Alternatively, however, only one of the housing parts 41, 42 could also be designed as a foil. Moreover, first housing part 41 and/or second housing part 42 may be designed to be optically transparent, at least in some areas. This may be achieved, in that first housing part 41 and/or second housing part 42 are/is designed to be so thin that an optical transparency is achieved. Alternatively, first housing part 41 and/or second housing part 42 encompass(es), for example, a material composition, which is permeable for optical radiation, in particular in a predefined wavelength range. Alternatively, first housing part 41 and/or second housing part 42 may also be coated, in areas, in such a way, that, in the corresponding area, the coating has an optical transparency only for optical radiation having a predefined wavelength.

Moreover, device 10 may be optionally at least partially coated with a coating 50. In particular, electronic unit 20 is at least partially coated with coating 50.

1-10. (canceled)

11. A device for monitoring an object, the device comprising:
an electronic unit configured to detect and store at least one surroundings parameter acting upon the object; and
a support element which is adhesive on a top side and on a bottom side, the electronic unit being situated on the top side of the support element and being adhesively connected to the top side of the support element, and the device being adhesively mountable at the object using the bottom side of the support element.

12. The device as recited in claim 11, wherein the support element is a foil, and is a double-sided adhesive tape.

13. The device as recited in claim 11, wherein the device includes a housing which includes a first housing part and a second housing part, the support element being the first housing part, and the second housing part being configured and situated in such a way that the electronic unit is at least partially enclosed by the housing.

14. The device as recited in claim 11, wherein the device is at least partially covered by a coating, and wherein the electronic unit is at least partially covered by the coating.

15. The device as recited in claim 11, wherein the electronic unit is configured to output pieces of information regarding the object.

16. The device as recited in claim 11, wherein the electronic unit is configured to output pieces of information regarding the at least one surroundings parameter acting upon the object.

17. The device as recited in claim 15, wherein the electronic unit includes a display element and is configured to output the pieces of information using the display element, the display element including a display and/or an illuminant.

18. The device as recited in claim 15, wherein the electronic unit includes a transducer element and is configured to convert the pieces of information into mechanical oscillations, the electronic unit being configured to output the mechanical oscillations using the transducer element, the transducer element including a loudspeaker.

19. The device as recited in claim 11, wherein the electronic unit includes a communication unit configured to communicate with an external unit.

20. The device as recited in claim 19, wherein the communication unit is a wireless communication unit.

21. The device as recited in claim 11, wherein the electronic unit includes an energy supply unit.

22. The device as recited in claim 11, wherein the electronic unit includes an energy store and/or an energy harvesting unit.

23. The device as recited in claim 11, wherein the electronic unit includes a battery and/or a capacitor.

24. The device as recited in claim 11, wherein the electronic unit includes at least one sensor unit and a memory element, the sensor unit including: (i) an acceleration sensor, and/or (ii) a rotation rate sensor, and/or (iii) a sound transducer, and/or (iv) an inclination sensor and/or (v) a light sensor, and/or (vi) a magnetic field sensor, and/or (vii) a temperature sensor, and/or (viii) a pressure sensor, and/or (ix) a moisture sensor.
